(19) United States
(12) Patent Application Publication
(10) Pub. No.: US 2010/0040983 A1
(43) Pub. Date: Feb. 18, 2010

(54) Compensation of Process-Induced Displacement

(75) Inventors: Heinrich Ollendorf, Dresden (DE); Thomas Zell, Dresden (DE); Michael Kubis, Dresden (DE); Steffen Schmidt, Dresden (DE); Elke Hietschold, Dresden (DE)

Correspondence Address: EDELL, SHAPIRO & FINNAN, LLC, 1901 RESEARCH BLVD., SUITE 400, ROCKVILLE, MD, 20850, US

(73) Assignee: Qimonda AG, Munich (DE)

(21) Appl. No.: 12/191,492

(22) Filed: Aug. 14, 2008

(51) Int. Cl. G03F 7/20

(52) U.S. Cl. 430/319

(57) ABSTRACT

A method of manufacturing integrated circuits includes determining a process-induced displacement (e.g., a stress-induced displacement) between primary structures on a substrate and providing a photomask with mask features assigned to the primary structures. The distances between the mask features are set such that the process-induced displacement is compensated.

### BACKGROUND

The fabrication of semiconductor devices involves lithography processes transferring a mask pattern on a photomask into a resist layer on a wafer and then transferring the pattern in the resist layer into a functional layer of the wafer. The patterns in a plurality of layers are aligned to each other and the dimensions of the pattern features and the spaces between the patterns features are provided with sufficient tolerance versus a misalignment of the various layers with reference to each other. For example, a displacement of a first conductive feature in one of the layers in relation to a second conductive feature in another layer may result in an open circuit condition or in significant deviations with regard to the ohmic resistance of the connection.

A need exists for methods of manufacturing integrated circuits with improved yield and/or smaller deviations between equivalent devices in the integrated circuits as well as for methods of manufacturing photomasks facilitating such methods.

### SUMMARY

A method of manufacturing integrated circuits as described herein includes determining a process-induced displacement between primary structures on a substrate. A photomask (e.g., compensating photomask) with mask features assigned to the primary structures is provided, wherein distances between the mask features are set such that the process-induced displacement is compensated.

According to another method of manufacturing an integrated circuit, a process-induced displacement of a first one of a plurality of primary structures assigned to one of a plurality of first substrate regions is determined with respect to a second one of the plurality of primary structures, wherein a process-induced displacement of the primary structures accumulates outwardly in each first substrate region and is at least partly compensated in one of a plurality of second substrate regions arranged between the first substrate regions. A photomask (e.g., compensating photomask) with a plurality of first mask patterns assigned to the first substrate regions is defined, wherein distances between mask features assigned to the primary structures is set or arranged such that the process-induced displacement of the primary structures is compensated.

The above and still further features and advantages of the present invention will become apparent upon consideration of the following definitions, descriptions and descriptive figures of specific embodiments thereof, wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

Features and advantages of embodiments of the invention will be apparent from the following description with reference to the accompanying drawings. The drawings are not necessarily to scale and emphasis is placed upon illustrating the principles. The features of the various illustrated embodiments can be combined with each other.

FIG. 1A illustrates a cross-sectional view of a substrate portion for illustrating an embodiment of a method of manufacturing an integrated circuit after forming cavities defined by a first mask.

FIG. 1B illustrates a cross-sectional view of the substrate portion of FIG. 1A after forming a primary pattern by filling the cavities with a material exerting a compressive stress.

FIG. 1C illustrates a cross-sectional view of the substrate portion of FIG. 1B after applying a secondary pattern defined by a second mask in accordance with a conventional method.

FIG. 1D illustrates a cross-sectional view of the substrate portion of FIG. 1B after applying a secondary pattern via a second mask in accordance with an embodiment of a method compensating stress-induced displacement via the second mask.

FIG. 1E illustrates a cross-sectional view of the substrate portion of FIG. 1B after applying a secondary pattern in accordance with an embodiment of a method compensating a stress-induced displacement via the first mask.

FIG. 2A illustrates a schematic plan view of a substrate portion with densely and sparsely populated substrate regions for illustrating a stress-induced displacement of primary structures.

FIG. 2B is a simplified diagram plotting the mechanical stress being locally effective versus a position on the substrate portion along line B-B of FIG. 2A.

FIG. 2C is a further simplified diagram plotting the stress-induced displacement of primary structures arranged in a virtual grid versus the position along line B-B of FIG. 2A.

FIG. 3A illustrates a plan view of a substrate portion with regularly arranged densely populated first substrate regions and sparsely populated second substrate regions separating the first substrate regions from each other for illustrating an application for an embodiment of a method of compensating a stress-induced displacement.

FIG. 3B illustrates a cross-sectional view along line B-B of FIG. 3A.

FIG. 3C is a simplified diagram plotting the stress-induced displacement of primary structures in densely populated first substrate regions.

FIG. 4A is a simplified flow chart illustrating a method of manufacturing an integrated circuit compensating a stress-induced displacement between primary structures in accordance with a further embodiment.

FIG. 4B is a simplified flow chart illustrating a method of manufacturing an integrated circuit compensating a stress-induced displacement between primary structures in densely populated substrate portions according to another embodiment.

FIG. 5 illustrates a schematic cross-sectional view of a substrate portion with a densely populated first substrate region and sparsely populated second substrate regions adjacent to the first substrate region for illustrating a further application for a method of compensating a plasma density induced displacement.

### DETAILED DESCRIPTION

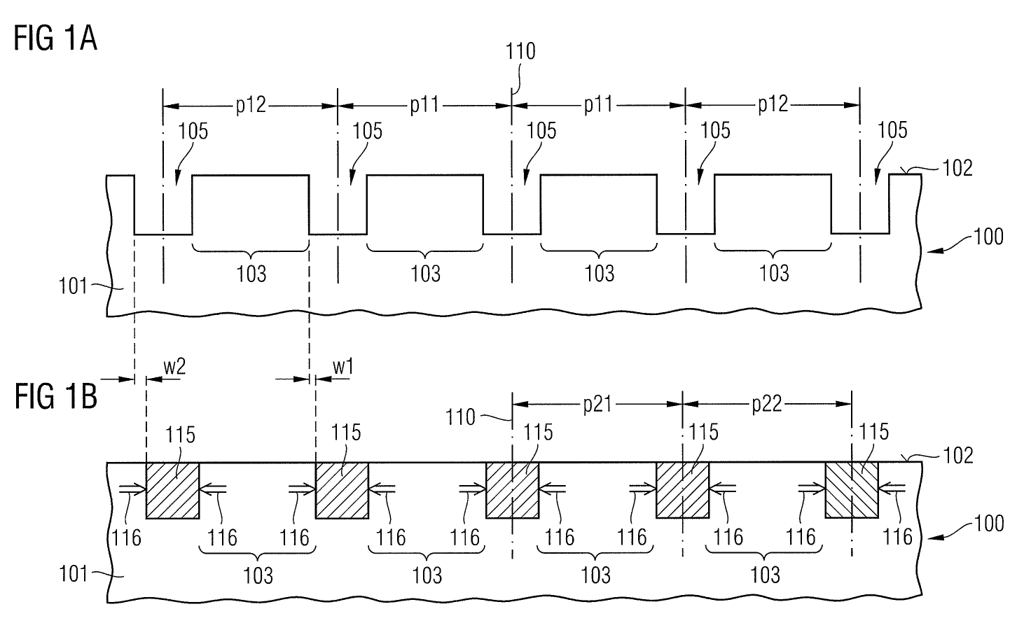

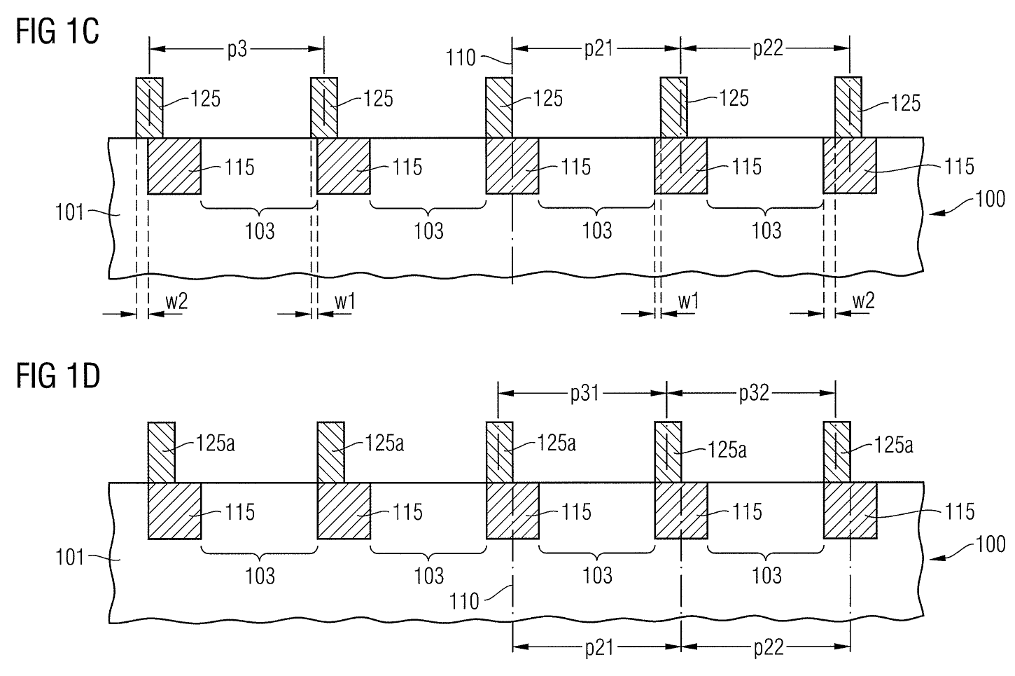

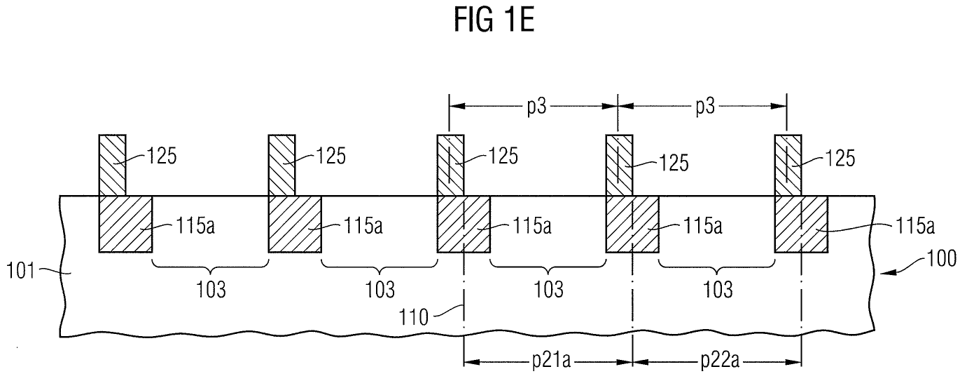

Referring to FIG. 1A, a plurality of equidistantly arranged cavities 105 may be defined by a lithography exposure process in a main surface 102 of a substrate 100. The cavities 105 may be holes or grooves arranged, for example, symmetric to a center line 110 along a line at a first pitches p11, p12, wherein the first pitches p11, 12 are defined by a first photomask (e.g., a reticle or a reflective mask) which is used in the lithography exposure process. The first pitches p11, p12 may be identical. In accordance with other embodiments, the cavities 105 may be arranged at different pitches p11, p12, wherein here and in the following, the term pitch refers to the distance between the center lines of the respective structures. The substrate 100 may be a pre-processed workpiece (e.g., a carrier consisting of or comprising glass or plastic, or a semiconductor wafer). According to an embodiment, the substrate 100 may be a semiconductor wafer or a SoI (semiconductor-on-insulator)-wafer, and may include further doped an undoped sections, epitaxial semiconducting layers as well as further conductive and insulating structures that have previously been fabricated. The semiconductor may be single crystalline silicon, germanium, gallium-arsenide or another semiconductor material. The cavities 105 may be embedded in a surrounding substrate portion 101 and may be line-shaped or dot-shaped with circular or elliptic cross sections or with a rectangular cross section with rounded corners. The main surface 102 is subjected to the majority of patterning processes in course of the formation of integrated circuits in the substrate 100. Lithography techniques like DUV (deep ultraviolet) or EUV (extreme ultraviolet) lithography and double patterning methods like cross patterning or pitch multiplication (pitch fragmentation) may be used to image a primary pattern including the cavities 105 into the substrate 100. In accordance with other embodiments, the cavities 105 may be formed in a layer disposed over the substrate 100.

The substrate 100 may be substantially stress-free and free from distortion and the main surface 102 may be substantially flat. In accordance with other embodiments, a mechanical stress may be effective between an upper portion of the substrate 100 adjoining the main surface 102 and a lower portion adjoining a rear side opposing the main surface 102. Such mechanical stress may result from the use of different substrate materials in the upper and the lower substrate portion or from features previously applied on or introduced into the upper portion. The main surface 102 may then be inwardly or outwardly bowed, for example in a concave or convex manner.

As illustrated in FIG. 1B, a fill material may be deposited into the cavities 105 to form primary structures 115 buried in the substrate 100. The fill material may induce a mechanical stress into the adjoining substrate portions 101 after its deposition or after a post-treatment (e.g., an anneal). For example, a thermal anneal of undoped, p-doped or n-doped polycrystalline silicon (polysilicon) may stimulate a crystallization process of the polycrystalline silicon which may result in an expansion of the fill material in the cavities. Other materials (e.g., deposited carbon) may densify during deposition or a post-treatment. Depending on the stiffness of the workpiece and the rigidity (elasticity modulus) of the fill material and the materials of the surrounding substrate portions, the cross-section of the primary structures 115 may expand or contract and/or the workpiece may be inwardly or outwardly bowed locally, wherein a compressive or tensile stress is induced into the surrounding substrate portion 101. An expanding fill material may exert a compressive stress and a contracting fill material may exert a tensile stress into the surrounding substrate portions.

In the illustrated embodiment, the primary structures 115 contract. Assumed a rather rigid surrounding substrate portion 101, second pitches p21, p22, at which the primary structures 115 are arranged, may be smaller than the first pitches p11, p12, due to the contraction of the primary structures 115 and/or a bowing induced by the resulting mechanical stress. The second pitches p21, p22 may be equal. The displacement w1, w2 of each primary structure 115 relative to the corresponding cavity 105 increases with increasing distance to the center line 110.

The stress-induced displacement as described herein is effective only in the vicinity of the primary structures 115. Depending on the total primary pattern, the placement of the primary structures within the primary pattern and the material properties, the local stress-induced effect may be compensated in a sufficient distance to the stress-inducing primary structures. Conventional methods dealing with wafer bowing like exposure field correction are effective over the whole workpiece and do not differentiate between locally stressed and un-stressed regions.

According to the illustrated embodiment, the fill material exerts a compressive stress 116. A segmented portion 103 of the substrate portion 101 between the primary structures 115 is rather rigid and may maintain its dimensions. Since the compressive stress is effective on one side of the wafer and decreases with increasing distance to the main surface 102, the wafer may bow such that the main surface 102 is locally concavely bowed. In other substrate portions, which are spaced from the primary structures 115 and which do not contain structures equivalent to the primary structures 115, no local distortion occurs or a local distortion may occur only to a negligible amount.

FIG. 1C refers to the formation of secondary structures 125 via a second lithography exposure via a second photomask, wherein the secondary structures 125 are aligned to the primary structures 115. Assumed that the first pitches p11, p12 are equal and a third pitch p3, at which the secondary structures 125 are arranged, is equal to the first pitches p11, p12, the secondary structures 125 can not be precisely aligned to the primary structures 115. A symmetric displacement with respect to the centerline 110 occurs. If the primary and the secondary structures 115, 125 are conductive structures, an ohmic resistance of a joint structure 115/125 near the center line 110 may deviate significantly from that of a joint structure 115/125 far apart from the center line 110. Further, even a slight misalignment of the two photomasks may result in an open circuit condition for joint structures 115/125 far apart from the center line 110. In the illustrated embodiment, the term “aligned” refers to structures being in direct contact with each other. According to other embodiments, the term “aligned” may refer to structures which are spaced to each other in a predetermined distance like gate electrodes and isolating regions separating active areas.

According to an embodiment illustrated in FIG. 1D, the stress-induced displacement between the primary structures 115 is determined by simulation, calculation or comparison measurements. Then a second photomask with mask features is defined, wherein the mask features correspond to secondary structures 125a. The distances between the mask features on the second photomask are defined such that the secondary structures 125a are spaced at third pitches p31, p32 which are equal to the corresponding second pitches p21, p22. Though explained in detail with regard to primary and secondary structures 115, 125 resulting directly from corresponding mask features, the same principles and considerations apply to structures, the formation and placement of which result indirectly from the mask features, for example, to structures emerging from the segmented substrate portions 103 or resulting from further self-aligned pattering processes or double patterning methods.

According to another embodiment as illustrated in FIG. 1E, a misalignment may be reduced by determining the first pitches p11, p12, at which the cavities 105 of FIG. 1A are arranged, such that the second pitches p21a, p22a, at which the resulting primary structures 115a are arranged, are equal to a target pitch p3 at which the secondary structures 125 are arranged. For that purpose, a stress-induced displacement between the two primary structures 115a is determined, for example, by simulation or by experiment (i.e., empirically). The stress-induced displacement may result from a compressive or tensile stress which the primary structures 115a induce or exert in the segmented substrate portions 103 in between. In the first photomask (e.g., compensating photomask), a primary mask pattern is defined with distances between the mask features assigned to the primary structures 115a set such that the stress-induced displacement between the primary structures 115a on the target substrate is compensated. In accordance with an embodiment, the first pitches p11, p12 between the cavities 105 of FIG. 1A are set such that the second pitches p21a, p22a between the primary structures 115a resulting from a fill of the cavities is equal to the target pitch p3 at which the secondary structures 125 are arranged.

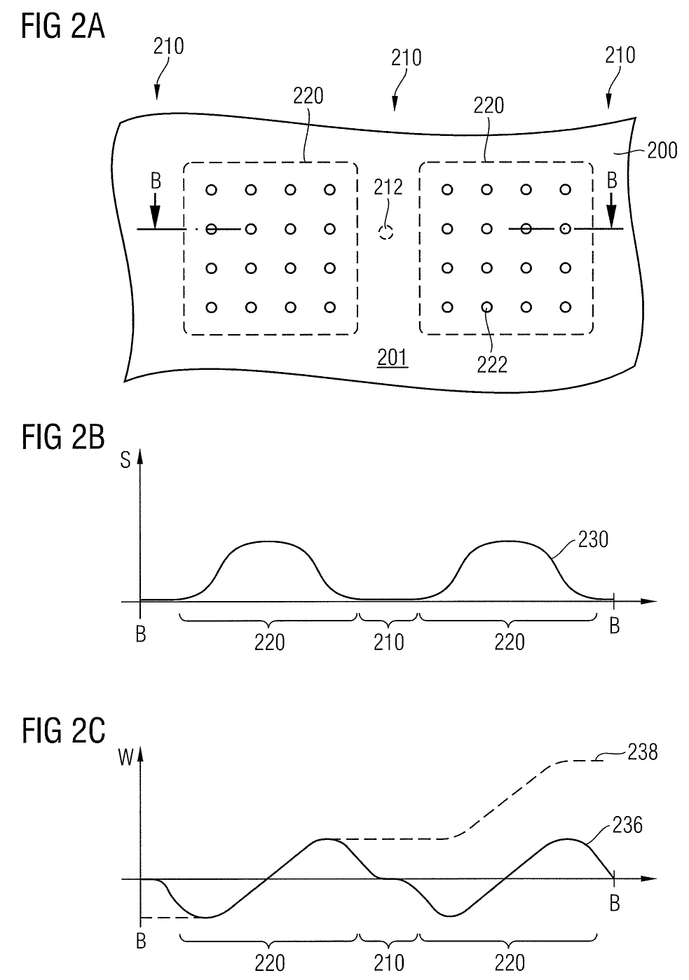

FIG. 2A refers to a primary pattern 200 in which sparsely populated regions 210 and densely populated regions 220 alternate. According to the illustrated embodiment, the densely populated regions 220 may include dot-shaped pattern features 222 which are arranged in matrices respectively, wherein the pattern features 222 are arranged at the nodes of a virtual regular grid, whereas the sparsely populated regions 210 do not contain any pattern features at all. In accordance with other embodiments, the pattern features 222 may be arranged in a irregular or rather arbitrary manner within the densely patterned regions 220 and the sparsely populated regions 210 may include few, isolated pattern features or may contain a plurality of pattern features arranged in a density which is significantly lower that that in the densely patterned regions 220. The mean pattern density in the densely populated regions 220 is significantly higher than in the sparsely populated regions 210 (e.g., twice as high or more). The pattern features 222 may deviate from each other in cross-sectional area and/or shape within the same region 210, 220 or from region to region and they may deviate with regard to the materials. The pattern features 222 may be contacts, capacitors, sensor cells, transistor cells, gate electrodes or any other conductive or dielectric features containing at least one material which differs from the materials of the surrounding substrate portion 201 and which is capable of inducing a mechanical stress into the substrate portion 201, for example, by contracting or expanding during a post-treatment. In accordance with another embodiment, the densely populated regions 222 are memory cell arrays with capacitors, wherein the storage electrodes of the capacitors are formed in trenches formed in the substrate portion 201. The sparsely populated regions 222 may refer to segment lines in which address and sense circuits are formed in a later process or to so-called “spines” and “belts” carrying further functional and/or test circuits, or to kerf areas in which the wafer is sawed.

FIG. 2B refers to a simplified diagram showing a curve 230 plotting the stress S which the pattern features 222 induce into the surrounding substrate portions 210 along line B-B of FIG. 2A. The stress induced by each pattern feature 222 adds up and may accumulate in the center of the densely populated regions 220 and decreases with increasing distance to the centers of the densely populated regions 220. According to the illustrated embodiment, the distance between the two densely populated regions 220 suffices to relieve the accumulated stress completely. In other embodiments, the distance between two of the densely populated regions 220 is too small to reduce the stress significantly.

FIG. 2C shows schematically the stress-induced displacement w of the pattern features 222 along line B-B of FIG. 2A with reference to a stress-free condition. A positive displacement w may be defined as a shift along the x-axis of FIG. 2C. Within each densely populated region 220, the displacement w changes slowly at the edge regions since only a few pattern features 222 induce effectively stress in the substrate portions surrounding the pattern feature 222 at the respective location. In the centers of the densely populated regions 220, the displacement w increases almost linearly as the same number of pattern features 222 is effective respectively. Within the sparsely populated regions 210, the stress-induced displacement w does not increase. The displacement w of an imaginary pattern feature 212 located on the line B-B between the two densely populated regions 220 may correspond approximately to that of the last pattern feature on the left hand side, assumed that the sparsely populated region 210 only transfers the mechanical stress. If the wafer is stiff or rigid enough, the compressive stress in the densely populated regions may be compensated, wherein a tensile stress is induced into the sparsely populated regions 210. Then, the displacement w of the imaginary pattern feature 212 may decrease with increasing distance to the densely populated region 220 on the left hand side. Consequently, the stress-induced displacement over a plurality of densely populated regions may accumulate as indicated by the dotted line 238 or is effective only within and near each densely populated region 220 as indicated by the contiguous line 236.

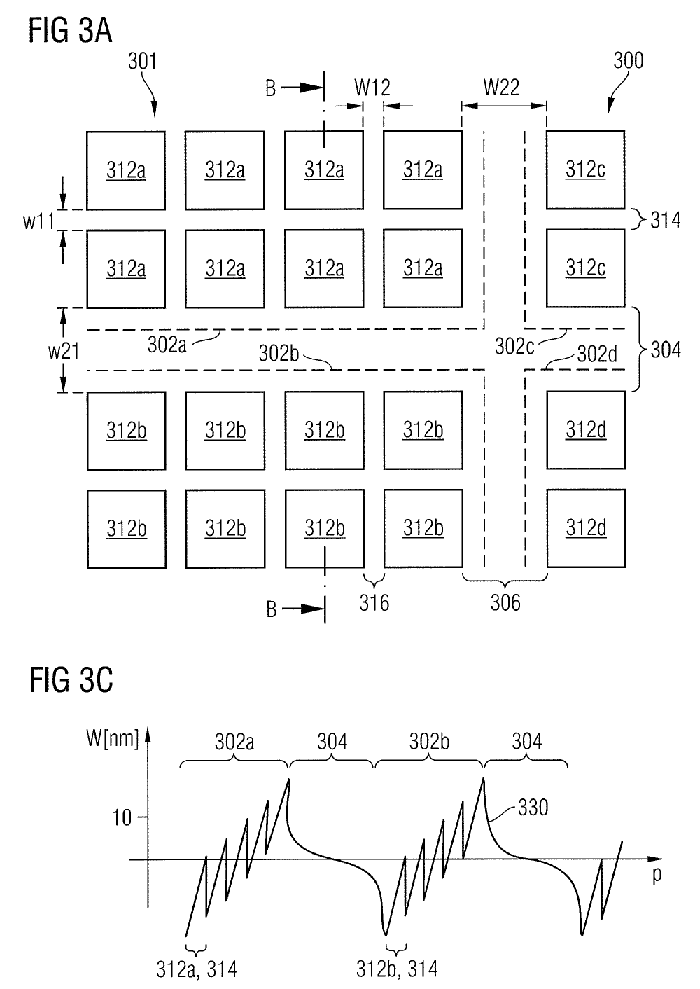

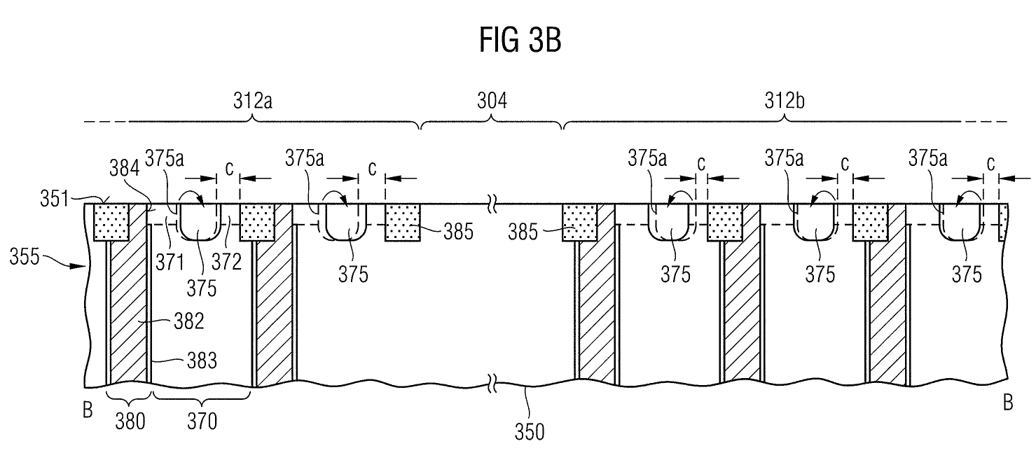

FIG. 3A refers to an application of a method of compensating a process-induced displacement and illustrates a substrate portion 301 of an integrated circuit 300 with a plurality of first substrate regions 302a-302d which include primary structures as illustrated in detail in FIG. 3B respectively. The primary structures induce a mechanical stress into the surrounding substrate portions embedding the primary structures, wherein the mechanical stress accumulates within the first substrate regions 302a-302d. Second substrate regions 304, 306 may contain no primary structures at all, or such primary structures which do not induce the same type of stress (e.g., compressive or tensile), or such primary structures that induce significantly less stress than that of the densely populated regions 302a-302d. The second substrate regions 304, 306 relieve at least partly the stress generated in the densely populated regions 302a-302d. Each densely populated region 302a-302d may comprise densely populated sub-regions 312a-312d and sparsely populated sub-regions 314, 316 separating the densely populated sub-regions 312a-312d.

Sufficient broad sparsely populated second substrate regions 304, 306 may relieve the accumulated mechanical stress completely such that the stress-induced displacement may be handled for each densely populated first substrate region 302a-302d in the same way. Sufficient broad sparsely populated second substrate regions 304, 306 on both opposing sides may balance the pattern shift such that the shift is low for pattern features in the center of the densely populated first substrate regions 302a-302d and the amount of the pattern shift is equal on both opposing edges. The narrower sparsely populated sub-regions 314, 316 do not necessarily relieve the accumulated mechanical stress completely.

FIG. 3B is a cross-sectional view of a section of the substrate portion 301 of FIG. 3A along line B-B. The cross-section intersects first primary structures arranged in two densely populated sub-regions 312a, 312b on opposing sides of a broad sparsely populated second substrate region 304. The first primary structures may be storage electrodes 382 of trench capacitors 380. The trench capacitors 380 segment active area lines 355 of single crystalline silicon (e.g., single crystalline semiconductor stripes). Isolation trench structures extending before and behind the cross-sectional plane parallel thereto separate neighboring active area lines 355 from each other. Each trench capacitor 380 may include a counter electrode which may be formed as a doped region within the semiconducting substrate 350, a capacitor dielectric between the storage and the counter electrode and an insulating collar 383 between the storage electrode and further substrate portions with access transistors 370. A contact strap 384 may electrically couple the respective storage electrode 382 to a first source/drain region 371 of an access transistor 370, which is assigned to the respective trench capacitor 380. An insulator structure 385 may insulate the storage electrode 382 and the neighboring non-assigned access transistor 370 in the same active area line 355. The access transistors 370 may be U-groove devices with the gate electrodes 375 buried below a main surface 351 of the substrate portion 350.

A first photomask defines trenches for the storage electrodes 382 in a first distance to each other within the active area lines 355 and the position of the storage electrodes 382. The position of the storage electrodes 382 determines the position of the second source/drain regions 372. Crystallization processes of the material of the storage electrodes 382 during or after deposition may generate tensile or compressive mechanical stress in the adjoining active area lines 355 and the isolation trench structures. The stress may shift the adjoining structures. In accordance with an embodiment, the active area segments approximately maintain their dimensions along the line B-B and the cross-sections of the storage electrodes change due to an expansion, a shrinkage and/or a bowing. For example, each storage electrode may shrink in case of densification or may expand in case of crystallization. The illustrated embodiment refers to shrinkage of the storage electrodes, wherein the distances between adjoining storage electrodes 382 are reduced with reference to a target distance between the unfilled trenches. A pattern shift results within each densely populated region 312a, 312b. The pattern shift is directed towards the center of the respective densely populated region. The amount of the shift depends on the number of storage electrodes which effectively induce stress in the respective densely populated region 312a, 312b, the amount of stress, Young's modulus of the materials involved, and further material properties.

The dotted lines refer to virtual gate electrodes 375a resulting from a virtual photomask and exposure process which would image the gate electrodes 375a displaced to the storage electrodes 382. The shift increases with increasing distance to the center of each densely populated substrate region. Depending on the actual design, a stress-induced pattern shift can be more critical at a first side of the first substrate sub-region 312a, 312b than at the other side. For example, the remaining contact width c for the second source/drain regions 372 may decrease significantly on the left hand side of the densely populated substrate region 312b on the right hand side of FIG. 3B, whereas the contact width c increases on the right hand side of the densely populated substrate region 312a on the left hand side of FIG. 3B. Considering the stress-induced displacement as discussed with reference to the previous figures, the gate electrodes 375 may be placed such that the contact widths c are approximately equal for all transistors 370. In accordance with other embodiments, the distances of mask features from which holes for the storage electrodes 382 result are adapted such that the resulting distances between the storage electrodes 382 fit with the target distances between the gate electrodes 375a, 375b.

Referring again to FIG. 3A, the densely populated first sub-regions 312a-312d may correspond to memory array segments, for example, of a DRAM (dynamic random access memory), and the sparsely populated second sub-regions 314, 316 correspond to segment lines that separate the memory array segments from each other and that have a width in the range of a few μm or less. A plurality (e.g., thirty two) of memory array segments may be arranged in alternating order with segment lines and form a cell region which may correspond to one of the densely populated first substrate regions 302a-302d. The sparsely populated second substrate regions 304, 306 may correspond to “spines” and “belts” separating neighboring cell regions and may be broad enough to relieve the accumulated stress. The width of the spines and belts may be in the range of several hundred μm or more. Two spines on opposing sides of the cell region balance the stress such that the maximum shift within each cell region appears at the edges, whereas the shift in the center of the cell region is marginal.

FIG. 3C is a diagram plotting the shift within two neighboring balanced cell regions isolated by spines as described in the previous paragraph. Each cell region includes a plurality of segments separated by segment lines. Within each segment the shift varies by approximately 10 nm. The accumulated shift between the first primary structure in the first segment and the last primary structure in the last segment may be approximately 30 nm. On a photomask, the distance between mask features assigned to the primary structures may alter (increase or decrease) monotonic, for example, strictly monotonic, and symmetric to the center of the densely populated sub-regions 312a-312d of FIG. 3A.

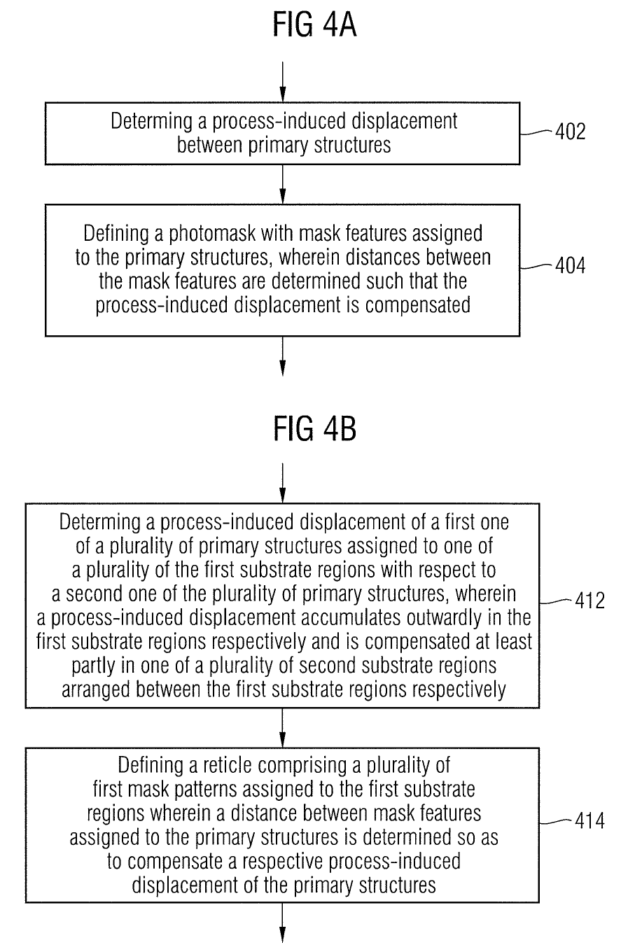

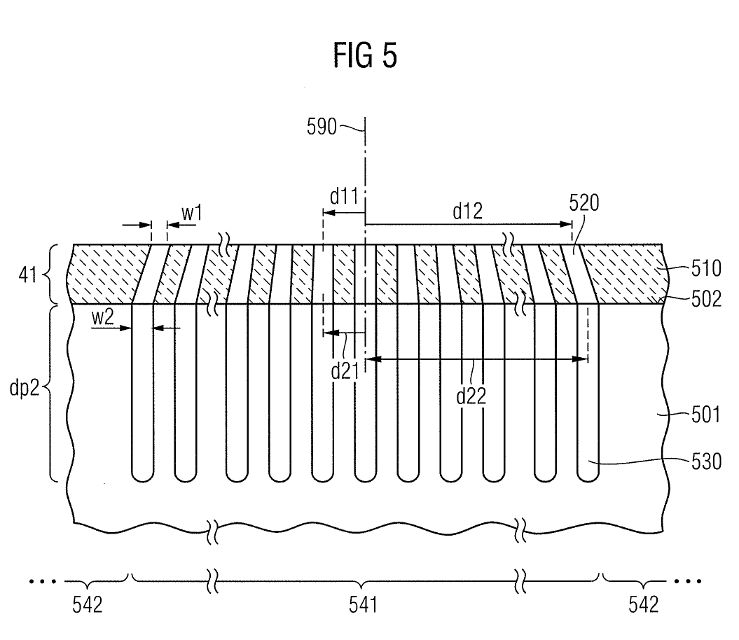

Referring to FIG. 4A, a method of fabricating an integrated circuit includes determining a stress-induced displacement between primary structures (402). On a photomask (e.g., compensating photomask), the distances between mask features, assigned to the primary structures are determined such that the stress-induced displacement is compensated (404).

In accordance with another method of fabricating an integrated circuit as illustrated in FIG. 4B, a stress-induced displacement of a first one of a plurality of primary features assigned to one of a plurality of first substrate regions with respect to a second one of the plurality of primary features is determined (412). Within the first substrate regions a mechanical stress accumulates outwardly and relieves at least partly in one of a plurality of second substrate regions arranged between the first substrate regions. On a photomask (e.g., compensating photomask) with first mask patterns assigned to the first substrate regions distances between mask features assigned to the primary features are determined so as to compensate the respective stress-induced displacement of the primary features (414).

FIG. 5 refers to a further application for a method of compensating a process induced displacement. A hard mask layer 510 (e.g., a silicon oxide or a silicon nitride layer) is disposed on a main surface 502 of a semiconductor substrate 501. In a first substrate region 541, which may be surrounded by second substrate regions 542, openings 520 are formed in the hard mask layer 510 via a lithographically patterned first resist layer and a first anisotropic etch process. The openings 520 may be holes or grooves. In the first resist layer and on the upper surface of the hard mask layer 510 the openings 520 may have a first width w1 and may be arranged at a distance d11 respectively at least along one axis. The patterned hard mask layer 510 serves as a further etch mask for etching, for example, holes or grooves 530, into the semiconductor substrate 501 via a second anisotropic etch process. The holes or grooves 530 may correspond to primary structures as described above. A second width w2 of the holes or grooves 530 at the main surface 502 may be approximately equal to, narrower than or wider than the first width w1. The hard mask layer 510 may have a first thickness th1 of about 1000 nm or more and the holes or grooves 530 may extend up to a depth dp2 of about 5000 nm or more.

The first and/or second anisotropic etch process may be a reactive ion beam etch using a plasma and/or an acceleration voltage. The local process conditions for each opening 520 and each hole or groove 530 may depend on proximity effects such that the etch result may depend on the number of neighboring openings 520 and/or holes or grooves 530 along each direction. With increasing etch depth, the proximity effects may bend the openings 520 outwardly in the direction of the second substrate portions 542 which contain no or significantly less openings 520 per area unit than the first substrate portion 541. As seen in FIG. 5, the openings 520 may be slightly bent or curved (i.e., bent, curved, angled or tilted with regard to the holes or grooves 530). The distances between the holes or grooves 530 increase with increasing distance to a center 590 of the first substrate portion 541. A distance d22 between a hole or groove 530 at the edge of the first substrate portion 541 and the center 590 may be greater than a distance d12 between the upper section of the corresponding opening 520 and the center 590.

The plasma-density induced bending may be measured, simulated or calculated and corrected either in a first photomask to pattern the first resist layer or in a second photomask to pattern a second resist layer to form secondary structures which are required to be aligned to the primary structures. Correction by adaptation of the first photomask may be effected by gradually reducing the distance between mask features assigned to the openings 520 with increasing distance to a mask pattern center corresponding to the center 590. Correction in a second photomask (e.g., compensating photomask) may be effected by gradually increasing the distance between mask features assigned to the secondary structures with increasing distance to a mask pattern center that corresponds to the center 590.

While the invention has been described in detail with reference to specific embodiments thereof, it will be apparent to one of ordinary skill in the art that various changes and modifications can be made therein without departing from the spirit and scope thereof. Accordingly, it is intended that the present invention covers the modifications and variations of this invention provided they come within the scope of the appended claims and their equivalents.

What is claimed is:

1. A method of manufacturing integrated circuits, the method comprising:
determining a process-induced displacement between primary structures; and
defining a compensating photomask with mask features assigned to the primary structures, wherein distances between the mask features are arranged such that the process-induced displacement is compensated.

2. The method of claim 1, further comprising:
forming primary structures via exposing the compensating photomask.

3. The method of claim 1, further comprising:
forming primary structures via exposing a first photomask; and
forming secondary structures aligned to the primary structures via exposing the compensating photomask.

4. The method of claim 1, wherein the process-induced displacement is a stress-induced displacement resulting from a fill/anneal sequence.

5. The method of claim 4, wherein the primary structures exert a mechanical stress on neighboring portions of a substrate which are in contact with the primary structures.

6. The method of claim 4, wherein the primary structures are filled cavities segmenting single crystalline semiconductor stripes.

7. The method of claim 4, wherein:
a first one and a second one of the primary structures are ones of a plurality of filled cavities segmenting a first single crystalline semiconductor stripe.

8. The method of claim 4, wherein:
a first one of the primary structures is one of a plurality of filled cavities segmenting a first single crystalline semiconductor stripe; and
a second one of the primary structures is one of a plurality of filled cavities segmenting a second single crystalline semiconductor stripe running in a longitudinal projection of the first stripe, the distance between the first and the second stripes being equal to or greater than a mean distance between the filled cavities within a respective one of the first and second stripes.

9. The method of claim 1, wherein the process-induced displacement is determined empirically.

10. A method of manufacturing an integrated circuit, the method comprising:
determining a process-induced displacement of a first one of a plurality of primary features assigned to one of a plurality of first substrate regions with respect to a second one of the plurality of primary features, wherein the process-induced displacement accumulates outwardly in the first substrate regions respectively and is compensated at least partly in one of a plurality of second substrate regions arranged between the first substrate regions respectively; and
defining a compensating photomask comprising a plurality of first mask patterns assigned to the first substrate regions, wherein distances between mask features assigned to the primary features are configured to compensate a respective process-induced displacement of the primary features.

11. The method of claim 10, wherein a feature density in the second substrate regions is lower than in the first substrate regions.

12. The method of claim 10, wherein the primary features are arranged in a regular grid.

13. The method of claim 12, wherein distances between the mask features assigned to the same substrate region alter monotonic and symmetric to a center of each first mask pattern.

14. The method of claim 12, wherein the first substrate regions are arranged in a regular grid.

15. The method of claim 10, wherein the process-induced displacement is a stress-induced displacement resulting from a fill/anneal sequence.

16. The method of claim 10, further comprising:
forming primary features via exposing the compensating photomask.

17. The method of claim 10, further comprising:
forming primary features via exposing a first photomask; and
forming secondary features aligned to the primary features via exposing the compensating photomask.

18. A method of manufacturing a photomask, the method comprising:
determining a process-induced displacement of a first one of a plurality of primary structures assigned to one of a plurality of first substrate regions with respect to a second one of the plurality of primary structures, wherein the process-induced displacement accumulates outwardly in the first substrate regions respectively and is compensated at least partly in one of a plurality of second substrate regions arranged between the first substrate regions respectively; and
defining a compensating reticle comprising a plurality of first mask patterns assigned to the first substrate regions, wherein a distance between mask features assigned to the primary structures is configured to compensate the respective process-induced displacement of the primary structures.

19. The method of claim 18, wherein the primary features are arranged in a regular grid.

20. The method of claim 19, wherein distances between the mask features assigned to the same substrate region alter monotonic and symmetric to a center of each first mask pattern.

21. The method of claim 19, wherein the first substrate regions are arranged in a regular grid.

22. The method of claim 21, wherein the distances between the mask features change accordingly in each first mask pattern.

23. The method of claim 18, wherein the process-induced displacement is a stress-induced displacement resulting from a fill/anneal sequence.
